(19) United States
(12) Patent Application Publication
(10) Pub. No.: US 2025/0167721 A1
(43) Pub. Date: May 22, 2025

(54) PHOTOVOLTAIC MODULE FOR A ROOF WITH CONTINUOUS FIBER TAPE

(71) Applicant: GAF Energy LLC, Parsippany, NJ (US)

(72) Inventors: William Sirski, San Jose, CA (US); Alex Sharenko, Berkeley, CA (US); David Fredric Joel Kavulak, Fremont, CA (US); Nathan Peterson, Oakland, CA (US); Hamsini Gopalakrishna, Santa Clara, CA (US)

(21) Appl. No.: 18/956,892

(22) Filed: Nov. 22, 2024

Related U.S. Application Data
(63) Continuation of application No. 17/972,401, filed on Oct. 24, 2022, now Pat. No. 12,191,797.
Application No. 17/972,401 is a continuation of application No. 17/675,957, filed on Feb. 18, 2022, now Pat. No. 11,496,088.
(60) Provisional application No. 63/151,510, filed on Feb. 19, 2021.

(51) Int. Cl. H02S 20/23; C09J 7/20; C09J 7/38; E04D 5/10; E04D 5/14

(52) U.S. Cl. CPC H02S 20/23; C09J 7/20; C09J 7/381; E04D 5/10; E04D 5/148

(57) ABSTRACT

Some embodiments of the present disclosure relate to photovoltaic module for use on a roof. In some embodiments, the photovoltaic module may include a solar cell and a polymeric continuous fiber tape. In some embodiments, the polymeric continuous fiber tape comprises a polymer and glass fiber. In some embodiments, the glass fiber is present in an amount greater than about 50% by weight based on a total weight of the polymeric continuous fiber tape. In some embodiments, the polymeric continuous fiber tape comprises an elastic modulus greater than 1 GPa and an optical transmission greater than 80%.

### CROSS-REFERENCE TO RELATED APPLICATIONS

This application is a continuation of U.S. patent application Ser. No. 17/972,401, filed Oct. 24, 2022, and titled “Photovoltaic Module for a Roof with Continuous Fiber Tape,” which is a continuation of U.S. patent application Ser. No. 17/675,957, filed Feb. 18, 2022, now U.S. Pat. No. 11,496,088, and titled “Photovoltaic Module for a Roof with Continuous Fiber Tape,” which claims priority to U.S. Provisional Application No. 63/151,510, filed on Feb. 19, 2021, and titled “Photovoltaic Module for a Roof with Continuous Fiber Tape,” the entire contents of which are incorporated by reference herein in their entirety.

### FIELD

The present disclosure relates to photovoltaic modules for roofs with continuous fiber tape and methods of manufacturing photovoltaic modules with continuous fiber tape.

### BACKGROUND

Some roofing systems include photovoltaic modules. In some instances, the photovoltaic modules may include solar cells and regions for protecting the solar cells.

### SUMMARY

Covered embodiments are defined by the claims, not this summary. This summary is a high-level overview of various aspects and introduces some of the concepts that are further described in the Detailed Description section below. This summary is not intended to identify key or essential features of the claimed subject matter, nor is it intended to be used in isolation to determine the scope of the claimed subject matter. The subject matter should be understood by reference to appropriate portions of the entire specification, any or all drawings, and each claim.

Some embodiments of the present disclosure are directed to a photovoltaic module for use on a roof, the photovoltaic module comprising: a solar cell, and a polymeric continuous fiber tape, wherein the polymeric continuous fiber tape comprises a polymer; and glass fiber, wherein the glass fiber is in an amount greater than about 55% by weight based on a total weight of the polymeric continuous fiber tape; and wherein the polymeric continuous fiber tape comprises an elastic modulus greater than 1 GPa; and an optical transmission greater than 80%.

In some embodiments, the glass fiber is in an amount from 55% by weight to 70% by weight based on a total weight of the polymeric continuous fiber tape.

In some embodiments, when the photovoltaic module is installed on a roof, the roof comprises a class A fire resistance rating according to UL 790.

In some embodiments, the polymeric continuous fiber tape comprises a flammability rating of V-2 to 5VA when tested according to UL 94.

In some embodiments, the polymeric continuous fiber tape comprises a dielectric strength from 20 kV/mm to 50 kV/mm when tested according to ASTM D149.

In some embodiments, the optical transmission of the polymeric continuous fiber tape is from 80% to 95%.

In some embodiments, the glass fiber comprises continuous glass fiber.

In some embodiments, the glass fiber comprises unidirectional glass fiber.

In some embodiments, the glass fiber comprises extruded glass fiber.

In some embodiments, the polymeric continuous fiber tape comprises a flexure strength in a direction of the continuous glass fiber from 150 MPa to 500 MPa according to ASTM D7624.

In some embodiments, the polymer comprises polyolefin.

In some embodiments, the polymeric continuous fiber tape comprises a thickness from 100 μm to 1000 μm.

In some embodiments, the polymeric continuous fiber tape comprises a thickness from 200 μm to 500 μm.

Some embodiments of the present disclosure are directed to a method comprising: obtaining glass fiber tape; obtaining a polymer; and combining the glass fiber tape and the polymer so as to form a polymeric continuous fiber tape comprising: glass fiber in an amount greater than about 55% by weight based on a total weight of the polymeric continuous fiber tape; an elastic modulus greater than 1 GPa; and an optical transmission greater than 80%.

In some embodiments, the glass fiber tape comprises extruded glass fiber tape.

In some embodiments, combining the glass fiber tape and the polymer includes combining the glass fiber tape and the polymer using a melt impregnation process.

In some embodiments, the glass fiber is in an amount from 55% by weight to 70% by weight based on a total weight of the polymeric continuous fiber tape.

In some embodiments, the optical transmission of the polymeric continuous fiber tape is from 80% to 95%.

In some embodiments, the glass fiber comprises continuous glass fiber.

In some embodiments, the glass fiber comprises unidirectional glass fiber.

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 depicts an exploded cross-sectional view of an exemplary embodiment of a photovoltaic module.

FIG. 2 depicts a cross-sectional view of an exemplary embodiment of a polymeric continuous fiber tape.

FIG. 3 depicts a graph showing the percent of optical transmission loss in polymeric continuous fiber tapes loaded with glass fiber in an amount greater than 50% by weight based on a total weight of the polymeric continuous fiber tape.

### DETAILED DESCRIPTION

Among those benefits and improvements that have been disclosed other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, terms such as “comprising” “including,” and “having” do not limit the scope of a specific claim to the materials or steps recited by the claim.

As used herein, the term “consisting essentially of” limits the scope of a specific claim to the specified materials or steps and those that do not materially affect the basic and novel characteristic or characteristics of the specific claim.

As used herein, terms such as “consisting of” and “composed of” limit the scope of a specific claim to the materials and steps recited by the claim.

As used herein, the term “continuous fiber” means an elongated strand of fiber.

As used herein, the term “tape” refers to a strip of material that is configured to adhere to a material.

As used herein, the term “continuous fiber tape” refers to a composite tape that includes continuous fiber.

As used herein, the term “polymeric continuous fiber tape” refers to a composite tape that includes a polymer and continuous fiber.

All prior patents, publications, and test methods referenced herein are incorporated by reference in their entireties.

Some embodiments of the present invention relate to a photovoltaic module. In some embodiments the photovoltaic module may be sized and/or shaped for use on a roof. In some embodiments, the photovoltaic module may be a solar panel. In some embodiments, the photovoltaic module may be a solar shingle. In some embodiments, the photovoltaic module may be a solar shingle that may be a comparable size and/or shape to asphalt shingles.

In some embodiments, the photovoltaic module includes a solar cell. In some embodiments, the photovoltaic module includes a plurality of solar cells. In some embodiments, the solar cell may include a top surface and a bottom surface. In some embodiments, the photovoltaic module may include at least one region stacked on the top surface of the solar cell. In some embodiments, the photovoltaic module may include at least one region stacked on the bottom surface of the solar cell.

In some embodiments, at least one region stacked on the top and/or bottom surface of the solar cell may include a polymeric continuous fiber tape. In some embodiments, the polymeric continuous fiber tape may include a polymer. In some embodiments, the polymer may include polyolefin, cyclic polyolefin, ethylene-vinyle acetate (“EVA”), polyurethane, epoxy, polyester, acrylic, or any combination thereof.

In some embodiments, the polymeric continuous fiber tape may include glass fiber. In some embodiments, the polymeric continuous glass fiber tape may include a sufficient amount of glass fiber so as to result in the polymeric continuous fiber tape comprising an elastic modulus greater than 1 Gpa when tested according to ASTM D638 and an optical transmission greater than 80%. In some embodiments, when the photovoltaic module is installed on a roof, the roof comprises a class A fire resistance rating according to UL 790.

In some embodiments, the sufficient amount of glass fiber may be an amount greater than 50% by weight based on a total weight of the polymeric continuous glass fiber tape. In some embodiments, the sufficient amount of glass fiber may be an amount greater than 55% by weight based on a total weight of the polymeric continuous glass fiber tape. In some embodiments, the sufficient amount of glass fiber may be an amount of 55% by weight to 90% by weight, of 55% by weight to 80% by weight, of 55% by weight to 70% by weight, or of 55% by weight to 60% by weight based on a total weight of the polymeric continuous glass fiber tape. In some embodiments, the sufficient amount of glass fiber may be an amount of 60% by weight to 90% by weight, of 70% by weight to 90% by weight, or of 80% by weight to 90% by weight based on a total weight of the polymeric continuous glass fiber tape. In some embodiments, the sufficient amount of glass fiber may be an amount of 60% by weight to 80% by weight based on a total weight of the polymeric continuous glass fiber tape.

In some embodiments, the polymeric continuous fiber tape with the sufficient amount of glass fiber has an optical transmission greater than 80%. In some embodiments, the polymeric continuous fiber tape has an optical transmission of 80% to 100%, of 80% to 95%, of 80% to 90%, of 80% to 85%, of 85% to 100%, of 90% to 100%, of 95% to 100%, or of 85% to 95%.

In some embodiments, the percent of optical transmission may be determined using a spectrophotometer, including for example, a PerkinElmer® Lambda 1050 spectrophotometer. In some embodiments, the percent of optical transmission may be determined using a spectrophotometer with an integrating sphere, including for example, a 270 mm integrating sphere.

In some embodiments, the polymeric continuous fiber tape with the sufficient amount of glass fiber has a dielectric strength greater than 20 kV/mm when tested according to ASTM D149. In some embodiments, the polymeric continuous fiber tape with the sufficient amount of glass fiber has a dielectric strength of 20 kV/mm to 50 kV/mm when tested according to ASTM D149, of 20 kV/mm to 45 kV/mm when tested according to ASTM D149, of 20 kV/mm to 40 kV/mm when tested according to ASTM D149, of 20 kV/mm to 35 kV/mm when tested according to ASTM D149, of 20 kV/mm to 30 kV/mm when tested according to ASTM D149, of 20 kV/mm to 25 kV/mm when tested according to ASTM D149, of 25 kV/mm to 50 kV/mm when tested according to ASTM D149, of 30 kV/mm to 50 kV/mm when tested according to ASTM D149, of 35 kV/mm to 50 kV/mm when tested according to ASTM D149, of 40 kV/mm to 50 kV/mm when tested according to ASTM D149, of 45 kV/mm to 50 kV/mm when tested according to ASTM D149, of 25 kV/mm to 45 kV/mm when tested according to ASTM D149, or of 30 kV/mm to 40 kV/mm when tested according to ASTM D149.

In some embodiments, the polymeric continuous fiber tape comprises a thickness of 100 μm to 1000 μm, of 200 μm to 1000 μm, of 300 μm to 1000 μm, of 400 μm to 1000 μm, of 500 μm to 1000 μm, of 600 μm to 1000 μm, of 700 μm to 1000 μm, of 800 μm to 1000 μm, of 900 μm to 1000 μm, of 100 μm to 900 μm, of 100 μm to 800 μm, 100 μm to 700 μm, 100 μm to 600 μm, of 100 μm to 500 μm, of 100 μm to 400 μm, 100 μm to 300 μm, 100 μm to 200 μm, 200 μm to 900 μm, 300 μm to 800 μm, 400 μm to 700 μm, or of 500 μm to 600 μm.

In some embodiments, the polymeric continuous fiber tape comprises a thickness of 200 μm to 500 μm, of 200 μm to 450 μm, of 200 μm to 400 μm, of 200 μm to 350 μm, of 200 μm to 300 μm, of 200 μm to 250 μm, of 250 μm to 500 μm, of 300 μm to 500 μm, of 350 μm to 500 μm, of 400 μm to 500 μm, of 450 μm to 500 μm, of 250 μm to 450 μm, or of 300 μm to 400 μm.

In some embodiments, the glass fiber may be continuous glass fiber, unidirectional glass fiber, extruded glass fiber, mat glass fiber, weave glass fiber, or any combination thereof.

In some embodiments, the polymeric continuous fiber tape comprises a flexure strength in the direction of the continuous glass fiber. In some embodiments, the polymeric continuous fiber tape with the sufficient amount of glass fiber has a flexure strength in the direction of the continuous glass fiber greater than 300 Mpa. In some embodiments, the polymeric continuous fiber tape with the sufficient amount of glass fiber has a flexure strength in the direction of the continuous glass fiber of 150 Mpa to 500 Mpa according to ASTM D7624.

In some embodiments, the polymeric continuous fiber tape with the sufficient amount of glass fiber has a flexure strength in the direction of the continuous fiber of 150 Mpa to 450 Mpa, of 150 Mpa to 400 Mpa, of 150 Mpa to 350 Mpa, of 150 Mpa to 300 Mpa, of 150 Mpa to 250 Mpa, of 150 Mpa to 200 Mpa, of 200 Mpa to 500 Mpa, of 250 Mpa to 500 Mpa, of 300 Mpa to 500 Mpa, of 350 Mpa to 500 Mpa, of 400 Mpa to 500 Mpa, of 450 Mpa to 500 Mpa, of 200 Mpa to 450 Mpa, of 250 Mpa to 400 Mpa, or of 300 Mpa to 350 Mpa according to ASTM D7624.

In some embodiments, the polymeric continuous fiber tape is configured to be flame resistant. In some embodiments, the polymeric continuous fiber tape comprises a flammability rating of V-2 to 5VA when tested according to UL 94.

In some embodiments, the polymeric continuous fiber tape may be a region stacked on the top surface of the solar cell. In some embodiments, the polymeric continuous fiber tape may be a region stacked on the bottom surface of the solar cell. In some embodiments, the photovoltaic module may include a plurality of regions of polymeric continuous fiber tape that may be stacked on the top and/or bottom surfaces of the solar cell. In some embodiments, the region of polymeric continuous fiber tape may be a single layer of polymeric continuous fiber tape. In some embodiments, the region of polymeric continuous fiber tape may include a plurality of layers of polymeric continuous fiber tape.

In some embodiments, the plurality of regions of polymeric continuous fiber tape may be stacked so that the continuous glass fiber in each region is parallel to one another. In some embodiments, the plurality of regions of polymeric continuous fiber tape may be stacked so that the continuous glass fiber in one region is perpendicular to the continuous glass fiber in another region. In some embodiments, the plurality of regions of polymeric continuous fiber tape may be stacked so that the continuous glass fiber in one region is angled relative to the continuous glass fiber in another region. In some embodiments, the angle may be 0 degrees to 90 degrees, 10 degrees to 90 degrees, 20 degrees to 90 degrees, 30 degrees to 90 degrees, 40 degrees to 90 degrees, 50 degrees to 90 degrees, 60 degrees to 90 degrees, 70 degrees to 90 degrees, 80 degrees to 90 degrees, 0 degrees to 80 degrees, 0 degrees to 70 degrees, 0 degrees to 60 degrees, 0 degrees to 50 degrees, 0 degrees to 40 degrees, 0 degrees to 30 degrees, to 0 degrees to 20 degrees, 0 degrees to 10 degrees, 10 degrees to 80 degrees, 20 degrees to 70 degrees, 30 degrees to 60 degrees, or 40 degrees to 50 degrees.

In some embodiments, the plurality of regions of polymeric continuous fiber tape may include a first polymeric continuous fiber tape, a second polymeric continuous fiber tape, and a third polymeric continuous fiber tape. In some embodiments, the first, second, and third polymeric continuous fiber tapes may be spaced apart from one another in the photovoltaic module. In some embodiments, the second polymeric continuous fiber tape may be in a region between the first polymeric continuous fiber tape and the third polymeric continuous fiber tape in the photovoltaic module.

In some embodiments, the thickness of each region of polymeric continuous fiber tape may be the same. In some embodiments, each region of polymeric continuous fiber tape may each include a different thickness.

In some embodiments, a distance between the first polymeric continuous fiber tape and the second polymeric continuous fiber tape is at least 1 mm. In some embodiments, a distance between the first polymeric continuous fiber tape and the second polymeric continuous fiber tape is 1 mm to 6 mm, 1 mm to 5 mm, 1 mm to 4 mm, 1 mm to 3 mm, 1 mm to 2 mm, 2 mm to 6 mm, 3 mm to 6 mm, 4 mm to 6 mm, 5 mm to 6 mm, 2 mm to 5 mm, or 3 mm to 4 mm.

In some embodiments, a distance between the first polymeric continuous fiber tape and the third polymeric continuous fiber tape is at least 1 mm. In some embodiments, a distance between the first polymeric continuous fiber tape and the third polymeric continuous fiber tape is 1 mm to 6 mm, 1 mm to 5 mm, 1 mm to 4 mm, 1 mm to 3 mm, 1 mm to 2 mm, 2 mm to 6 mm, 3 mm to 6 mm, 4 mm to 6 mm, 5 mm to 6 mm, 2 mm to 5 mm, or 3 mm to 4 mm.

In some embodiments, a distance between the second polymeric continuous fiber tape and the third polymeric continuous fiber tape is at least 1 mm. In some embodiments, a distance between the second polymeric continuous fiber tape and the third polymeric continuous fiber tape is 1 mm to 6 mm, 1 mm to 5 mm, 1 mm to 4 mm, 1 mm to 3 mm, 1 mm to 2 mm, 2 mm to 6 mm, 3 mm to 6 mm, 4 mm to 6 mm, 5 mm to 6 mm, 2 mm to 5 mm, or 3 mm to 4 mm.

In some embodiments, the photovoltaic module may include a transparent sheet. In some embodiments, the transparent sheet may be a region stacked on the top surface of the solar cell. In some embodiments, the transparent sheet may include any sufficiently transparent material, including for example, glass. In some embodiments, the photovoltaic module does not have a transparent sheet.

In some embodiments, the transparent sheet has a thickness of 10 μm to 200 μm, of 10 μm to 180 μm, of 10 μm to 160 μm, of 10 μm to 140 μm, of 10 μm to 120 μm, of 10 μm to 100 μm, of 10 μm to 80 μm, of 10 μm to 60 μm, of 10 μm to 40 μm, of 10 μm to 20 μm, of 30 μm to 200 μm, of 50 μm to 200 μm, of 70 μm to 200 μm, of 90 μm to 200 μm, of 110 μm to 200 μm, of 130 μm to 200 μm, of 150 μm to 200 μm, of 170 μm to 200 μm, of 190 μm to 200 μm, of 30 μm to 180 μm, of 50 μm to 160 μm, of 70 μm to 140 μm, or of 90 μm to 120 μm.

In some embodiments, the photovoltaic module may include an encapsulant. In some embodiments, the encapsulant may be a region stacked on the top or bottom surface of the solar cell. In some embodiments, the photovoltaic module may include a plurality of regions of encapsulant stacked on the top and/or bottom surface of the solar cell. In some embodiments, the encapsulant may include polyolefin, silicone, EVA, or any combination thereof.

In some embodiments, the encapsulant has a thickness of 200 μm to 1000 μm, of 200 μm to 900 μm, of 200 μm to 800 μm, of 200 μm to 700 μm, of 200 μm to 600 μm, of 200 μm to 500 μm, of 200 μm to 400 μm, of 200 μm to 300 μm, of 300 μm to 1000 μm, of 400 μm to 1000 μm, of 500 μm to 1000 μm, of 600 μm to 1000 μm, of 700 μm to 1000μm, of 800 μm to 1000 μm, of 900 μm to 1000 μm, of 300 μm to 900 μm, of 400 μm to 800 μm, or of 500 μm to 700 μm.

In some embodiments, the photovoltaic module may include a core. In some embodiments, the core may be a region stacked on the top or bottom surface of the solar cell. In some embodiments, the core may include closed cell foam, open cell foam, honeycomb board, a pure polymer material, including, for example, thermoplastic polyolefin, or any combination thereof.

In some embodiments, the core has a thickness of 800 μm to 2000 μm, of 900 μm to 2000 μm, of 1000 μm to 2000 μm, of 1100 μm to 2000 μm, of 1200 μm to 2000 μm, of 1300 μm to 2000 μm, of 1400 μm to 2000 μm, of 1500 μm to 2000 μm, of 1600 μm to 2000 μm, of 1700 μm to 2000 μm, of 1800 μm to 2000 μm, of 1900 μm to 2000 μm, of 800 μm to 1900 μm, of 800 μm to 1800 μm, of 800 μm to 1700 μm, of 800 μm to 1700 μm, of 800 μm to 1600 μm, of 800 μm to 1500 μm, of 800 μm to 1400 μm, of 800 μm to 1300 μm, of 800 μm to 1200 μm, of 800 μm to 1100 μm, of 800 μm to 1000 μm, of 800 μm to 900 μm, of 900 μm to 1900 μm, of 1000 μm to 1800 μm, of 1100 μm to 1700 μm, of 1200 μm to 1600 μm, or of 1300 μm to 1500 μm.

In some embodiments, the solar cell may include a top surface and a bottom surface. In some embodiments, the photovoltaic module may include at least one region stacked on the top surface of the solar cell. In some embodiments, the photovoltaic module may include at least one region stacked on the bottom surface of the solar cell.

Some embodiments of the present disclosure may relate to a method. In some embodiments, the method may include obtaining glass fiber tape. In some embodiments, the glass fiber tape may be continuous glass fiber tape, extruded glass fiber tape, unidirectional glass fiber tape, or any combination thereof.

In some embodiments, the method may include obtaining a polymer. In some embodiments, the polymer may include polyolefin, including, for example, polyethylene, polypropylene, or combinations thereof.

In some embodiments, the method may include combining the glass fiber tape and the polymer so as to form a polymeric continuous fiber tape as described herein. For example, in some embodiments, the polymeric continuous fiber tape may include glass fiber in amount greater than 55% by weight based on a total weight of the polymeric continuous fiber tape, a strength module greater than 1 Gpa, and an optical transmission greater than 80%.

In some embodiments, the glass fiber tape and the polymer may be combined using a melt impregnation process. In some embodiments, the melt impregnation process includes impregnating the glass fiber tape with the polymer so as to form the polymeric continuous fiber tape.

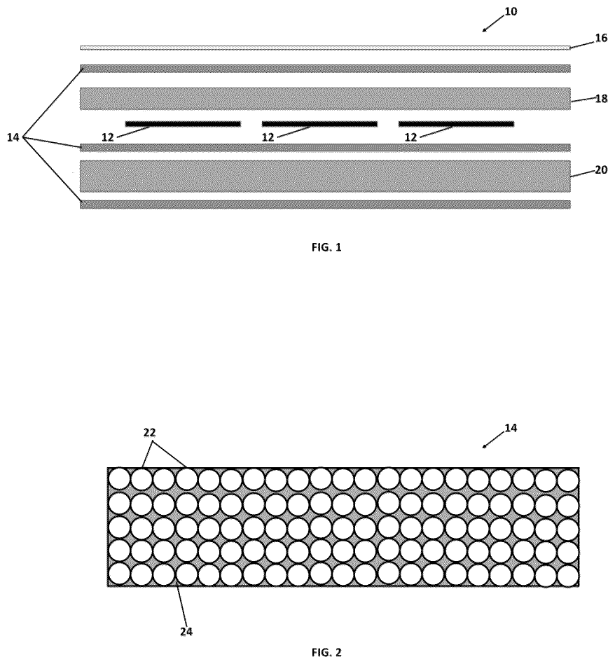

The present disclosure will now be described with reference to non-limiting exemplary embodiments depicted in FIGS. 1-3.

FIG. 1 depicts an exploded cross-sectional view of an exemplary embodiment of a photovoltaic module 10. As shown in FIG. 1, the photovoltaic module includes a plurality of solar cells 12 and a plurality of regions 14, 16, 18, 20 stacked above and below the solar cells 12. In the exemplary embodiment of FIG. 1, the plurality of regions includes three regions of polymeric continuous fiber tape 14. As shown in FIG. 1, the polymeric continuous fiber tape 14 is disposed in the photovoltaic module 10 above and below the solar cells 12. In addition, the plurality of regions includes a transparent sheet 16, an encapsulant 18, and a core 20.

FIG. 2 depicts a cross-sectional view of an exemplary embodiment of a polymeric continuous fiber tape 14. As shown in FIG. 2, the polymeric continuous fiber tape includes glass fiber 22. In the exemplary embodiment of FIG. 2, the glass fiber 22 is continuous glass fiber, which may be unidirectional and distributed throughout the polymeric continuous fiber tape. In addition, as shown in FIG. 2, the polymeric continuous fiber tape includes a polymer 24. In the exemplary embodiment of FIG. 2, the polymer 24 may be a polyolefin. The polyolefin may be impregnated in the polymeric continuous fiber tape.

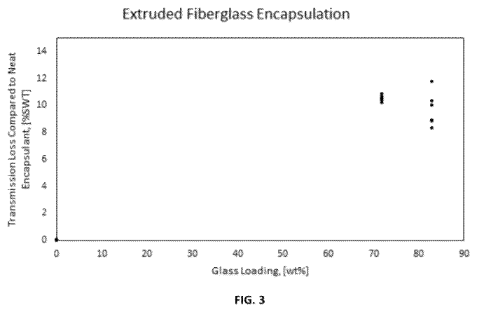

FIG. 3 depicts a graph showing the percent of optical transmission loss in samples of polymeric continuous fiber tapes loaded with glass fiber. The samples of polymeric continuous fiber tape were loaded with glass fiber in an amount greater than 50% by weight based on a total weight of the polymeric continuous fiber tape in accordance with the method described above. The amount of optical transmission for each sample was then tested using a PerkinElmer® Lambda 1050 spectrophotometer with a 270 mm integrating sphere. The obtained spectra for each sample was then weighted against the AM 1.5 standard solar spectrum. In addition, the amount of optical transmission for an encapsulant not loaded with glass fiber was obtained. The percent of optical transmission loss was obtained by comparing the optical transmission of each sample to the optical transmission of the encapsulant not loaded with glass fiber.

Variations, modifications and alterations to embodiments of the present disclosure described above will make themselves apparent to those skilled in the art. All such variations, modifications, alterations and the like are intended to fall within the spirit and scope of the present disclosure, limited solely by the appended claims.

While several embodiments of the present disclosure have been described, it is understood that these embodiments are illustrative only, and not restrictive, and that many modifications may become apparent to those of ordinary skill in the art. For example, all dimensions discussed herein are provided as examples only, and are intended to be illustrative and not restrictive.

Any feature or element that is positively identified in this description may also be specifically excluded as a feature or element of an embodiment of the present as defined in the claims.

The disclosure described herein may be practiced in the absence of any element or elements, limitation or limitations, which is not specifically disclosed herein. Thus, for example, in each instance herein, any of the terms “comprising,” “consisting essentially of and “consisting of” may be replaced with either of the other two terms, without altering their respective meanings as defined herein. The terms and expressions which have been employed are used as terms of description and not of limitation, and there is no intention in the use of such terms and expressions of excluding any equivalents of the features shown and described or portions thereof, but it is recognized that various modifications are possible within the scope of the disclosure.

1-20. (canceled)

21. A system, comprising:
a plurality of photovoltaic modules installed on a roof deck, wherein each of the plurality of photovoltaic modules includes
at least one solar cell,
a first region above the at least one solar cell,
wherein the first region includes a first continuous fiber tape,
wherein the first continuous fiber tape includes continuous glass fiber extending in a first direction,
wherein the first continuous fiber tape has a first flexure strength in the first direction,
a second region below the at lest one solar cell,
wherein the second region includes a second continuous fiber tape,
wherein the second continuous fiber tape includes continuous glass fiber extending in a second direction,
wherein the second continuous fiber tape has a second flexure strength in the second direction.

22. The system of claim 21, wherein each of the first continuous fiber tape and the second continuous fiber tape includes a polymer.

23. The system of claim 21, wherein the first continuous fiber tape has a first flexure strength in the first direction of 150 Mpa to 500 Mpa.

24. The system of claim 23, wherein the second continuous fiber tape has a second flexure strength in the second direction of 150 Mpa to 500 Mpa.

25. The system of claim 21, wherein the first region includes a single layer of the first continuous fiber tape.

26. The system of claim 21, wherein the second region includes a single layer of the second continuous fiber tape.

27. The system of claim 21, wherein the first region includes a plurality of layers of the first continuous fiber tape.

28. The system of claim 21, wherein the second region includes a plurality of layers of the second continuous fiber tape.

29. The system of claim 21, wherein the first direction is parallel to the second direction.

30. The system of claim 21, wherein the first direction is perpendicular to the second direction.

31. The system of claim 21, wherein the first direction is oblique to the second direction.

32. The system of claim 21, wherein the first direction is 0 degrees to 90 degrees relative to the second direction.

33. The system of claim 21, wherein a distance between the first continuous fiber tape and the second continuous fiber tape is 1 mm to 6 mm.

34. The system of claim 21, wherein each of the plurality of photovoltaic modules includes a third region, wherein the third region includes a third continuous fiber tape, wherein the third continuous fiber tape includes continuous glass fiber extending in a third direction.

35. The system of claim 34, wherein the third region is between the first region and the second region.

36. The system of claim 34, wherein the third region is below the second region.

37. The system of claim 34, wherein the third continuous fiber tape has a third flexure strength in the third direction.

38. The system of claim 37, wherein the third direction is 0 degrees to 90 degrees relative to the second direction.

39. A system, comprising:
a plurality of photovoltaic modules installed on a roof deck, wherein each of the plurality photovoltaic modules includes
at least one solar cell,
a first region above the at least one solar cell,
wherein the first region includes a first continuous fiber tape,
wherein the first continuous fiber tape includes continuous glass fiber extending in a first direction,
wherein the first continuous fiber tape has a first flexure strength in the first direction, and
a second region below the at least one solar cell,
wherein the second region includes a second continuous fiber tape,
wherein the second continuous fiber tape includes continuous glass fiber extending in a second direction,
wherein the second continuous fiber tape has a second flexure strength in the second direction,
a third region above the first region,
wherein the third region is an upper most region of the photovoltaic module, and
a fourth region below the second region.

40. A photovoltaic module, comprising:
at least one solar cell;
a first region above the at least one solar cell,
wherein the first region includes a first continuous fiber tape,
wherein the first continuous fiber tape includes continuous glass fiber extending in a first direction,
wherein the first continuous fiber tape has a first flexure strength in the first direction; and
a second region below the at least one solar cell,
wherein the second region includes a second continuous fiber tape,
wherein the second continuous fiber tape includes continuous glass fiber extending in a second direction, and
wherein the second continuous fiber tape has a second flexure strength in the second direction.
